(19) United States
(12) Patent Application Publication
(10) Pub. No.: US 2006/0009030 A1
(43) Pub. Date: Jan. 12, 2006

(54) Novel barrier integration scheme for high-reliability vias

(75) Inventors: Alfred J. Griffin JR., Dallas, TX (US); Edmund Burke, Dallas, TX (US); Asad M. Haider, Plano, TX (US); Kelly J. Taylor, Allen, TX (US); Tae S. Kim, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/175,174

(22) Filed: Jul. 7, 2005

Related U.S. Application Data
(60) Provisional application No. 60/586,787, filed on Jul. 8, 2004.

(51) Int. Cl. H01L 21/4763; H01L 21/44

(52) U.S. Cl. 438/637; 438/672; 438/644

(57) ABSTRACT

Disclosed is a method of fabricating an integrated circuit comprising patterning a dielectric layer to form a hole having a sidewall and a bottom. The hole can expose an underlying material of an electrically conducting material. The method also includes exposing the sidewall and the exposed underlying material to a plasma etch, depositing a barrier layer on the bottom and the sidewall of the hole after the plasma etch clean, forming a counter-sunk cone in the underlying material by etching through the barrier layer at the bottom of the hole into the conducting metal underneath, flash depositing a thin layer of the barrier material into the hole, and finally depositing a metal seed layer in the hole covering the sidewalls and the bottom of the hole including the cone at the bottom. The hole is finally filled by depositing a metal layer in the hole.

### DESCRIPTION OF THE INVENTION

This application claims the priority benefit of U.S. Provisional Patent Application Ser. No. 60/586,787 filed Jul. 8, 2004.

### FIELD OF THE INVENTION

The subject matter of this application relates to semiconductor devices and methods of making semiconductor devices having an electrical contact. More particularly, the subject matter of this application relates to semiconductor devices and methods of making semiconductor devices having a copper contact plug formed in a hole, where the hole can have a trench at the bottom.

### BACKGROUND OF THE INVENTION

Conventional techniques used to form a copper plug in a semiconductor device use a physical sputter etch comprising, for example, argon or other relatively large atoms, to clean and prepare vias formed in dielectrics for copper plug fills. However, physical etching sputters copper from the metal layer underneath the via bottom onto the via sidewalls. The sputtered copper can diffuse into the dielectric and degrade the dielectric quality of the material. Further, vias can be formed in low-k dielectric, which can be porous. The porous nature of low-k dielectrics increases the potential for unwanted copper diffusion and dielectric degradation.

For example, as shown in FIG. 1A there is a conventional via structure 100 having a copper layer 10 with a dielectric 20 formed thereover. A photoresist (not shown) is used to pattern and form a via 30 in dielectric 20. Via 30 exposes copper layer 10 at a bottom portion 32 of via 30. After via 30 is formed, photoresist residue typically remains at least on a sidewall 34 and bottom 32 of via 30.

As shown in FIG. 1B, a conventional physical etch 40, such as an argon sputter etch is used to remove the photoresist residue from the inside profile of via 30 and to remove any films or impurities, such as oxides, that may have formed on the exposed copper 10. Because the argon sputter etch 40 is a physical etch, copper 42 is sputtered from bottom 32 of via 30 onto sidewalls 34. As a result of thermal gradients and temperature cycling during regular processing of the wafer, copper 42 diffuses into dielectric 20 and degrades the dielectric properties of the material.

Further, as shown in FIG. 1C, the process of via formation in layered dielectric films followed by a plasma clean with physical etch 40 creates recess imperfections, such as notches and seams 44, in dielectric 20. Notches and seams 44 form at the interface between dielectric 20 and an underlying dielectric 12 and overlying dielectric 24, both of which may also be present. In addition, physical etch 40 can remove a thin layer, for example about 100 Å thick, of the exposed portion of copper 10 at bottom 32 of via 30. The removed copper can be deposited as copper 42 directly on sidewall 34 of dielectric 20 and also inside the notches 44 from where it can diffuse into dielectric 20 during further processing. This also results in the exposed copper 10 at bottom 32 of via 30 being damaged during the physical sputter etch. For example, atomic vacancies and surface irregularities can result from the physical etch. Al1 of these can contribute to poor contact performance.

Accordingly, the present invention solves these and other problems of the prior art when forming an electrical contact to a metal line in a semiconductor device.

### SUMMARY OF THE INVENTION

In accordance with the invention, there is a method of fabricating an integrated circuit comprising patterning a dielectric material to form a hole (also called a via) having a sidewall and a bottom, wherein the hole exposes an underlying material, wherein the exposed underlying material comprising an electrically conducting material. The method also comprises exposing the sidewall and the exposed underlying material to a plasma etch, depositing a barrier layer on the bottom and the sidewall of the hole after the plasma etch, etching a cone in the underlying material by etching through the barrier layer at the bottom of the hole, and depositing a metal layer in the cone/hole.

According to another embodiment, there is provided a method of fabricating an integrated circuit comprising patterning a dielectric material to form a hole which exposes an underlying material, the exposed underlying material comprising an electrically conducting material. Further, the method comprises exposing a sidewall of the hole and the exposed underlying material to a plasma etch clean. The method also comprises depositing a barrier layer onto the sidewall and the exposed underlying material, wherein the sidewall is substantially free of the electrically conducting material, and depositing a metal layer in the hole.

According to another embodiment, there is provided a method of fabricating an integrated circuit comprising patterning a dielectric material to form a hole having a sidewall and a bottom, wherein the hole exposes an underlying material comprising an electrically conducting material, and depositing a barrier layer onto the sidewall and bottom of the hole. The method also comprises removing a portion of the barrier layer at the bottom of the hole to expose a portion of the electrically conducting material, forming a counter-sinked cone in the exposed electrically conducting material, wherein the cone extends to a depth at least 300 Å into the layer of electrically conducting material, and depositing a metal layer over the sidewalls and in the notched areas 44 of the hole.

According to another embodiment, there is provided a method of fabricating an integrated circuit comprising patterning a dielectric material to form a hole having a sidewall and a bottom, wherein the hole exposes an underlying material comprising an electrically conducting material, exposing the hole to a temperature greater than about 200° C., and cooling the dielectric material to between about 10° C. to about 50° C. The method also comprises depositing a barrier layer onto the sidewall and bottom of the hole, sputtering through the barrier layer at the bottom of the hole, and sputtering the electrically conducting material to form a counter-sinked cone in the electrically conducting material. Further, a metal layer is deposited into the hole.

According to another embodiment, there is provided an integrated circuit device comprising a dielectric material formed over an underlying material, the underlying material comprising an electrically conducting material, a hole patterned in the dielectric material, and a barrier layer lining a portion of the hole. The device also includes a counter-sinked cone in the bottom of the hole, wherein the cone extends to a depth of at least about 300 Å into the layer of electrically conducting material, and a metal layer lining the hole and the cone.

According to another embodiment, there is provided an integrated circuit device comprising a dielectric material formed over an underlying material, the underlying material comprising an electrically conducting material, a hole patterned in the dielectric material, and a barrier layer lining a portion of the hole. The device also includes an opening in the barrier layer at a bottom of the hole, counter-sinked cone in the bottom of the hole exposed by the opening in the barrier layer, wherein the cone extends to about one quarter to about one half of the thickness of the electrically conducting material into the layer of electrically conducting material, and a metal layer lining the hole and the cone.

According to another embodiment, there is provided an integrated circuit device comprising a dielectric material formed over an underlying material, the underlying material comprising an electrically conducting material, a hole patterned in the dielectric material, and a barrier layer lining a portion of the hole. The device also includes an opening in the barrier layer at a bottom of the hole, a cone at the bottom of the hole exposed by the opening in the barrier layer and extending into the layer of electrically conducting material, and a metal layer lining the hole and the cone at the bottom of the hole.

It is to be understood that both the foregoing general description and the following detailed description are exemplary and explanatory only and are not restrictive of the invention, as claimed.

The accompanying drawings, which are incorporated in and constitute a part of this specification, illustrate one (several) embodiment(s) of the invention and together with the description, serve to explain the principles of the invention.

### BRIEF DESCRIPTION OF THE DRAWINGS

FIGS. 1A-1C are fragmentary cross-sectional diagrams of forming a conventional contact plug in a semiconductor device;

FIGS. 2A-2I are fragmentary cross-sectional diagrams illustrating various steps in forming a semiconductor device in accordance with various embodiments of the present invention;

FIG. 3A-3L are fragmentary cross-sectional diagrams illustrating various steps in forming a semiconductor device in accordance with other various embodiments of the present invention;

FIG. 4A-4E are fragmentary cross-sectional diagrams illustrating various steps in forming a semiconductor device in accordance with other various embodiments of the present invention; and

FIGS. 5A-5I are cross-sectional representations of hole and trench profiles according to various embodiments of the present invention.

FIGS. 6A and 6B depict graphical representations of exemplary cone sidewall angles according to various embodiments of the invention.

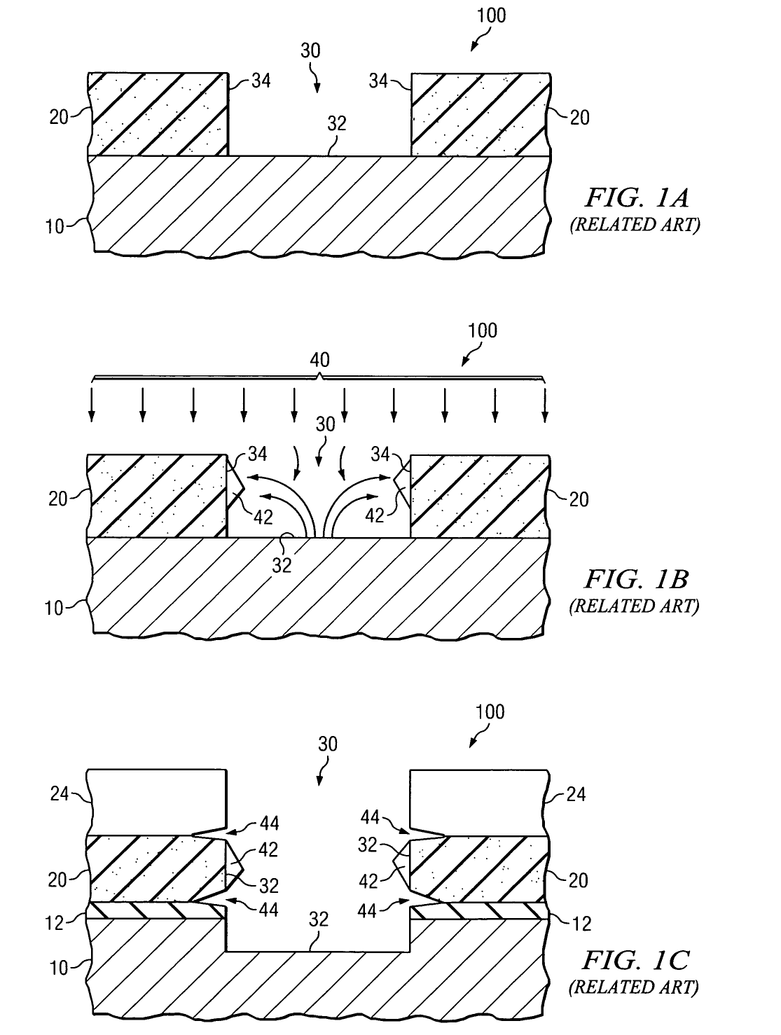

### DESCRIPTION OF THE EMBODIMENTS

Reference will now be made in detail to the present embodiments (exemplary embodiments) of the invention, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

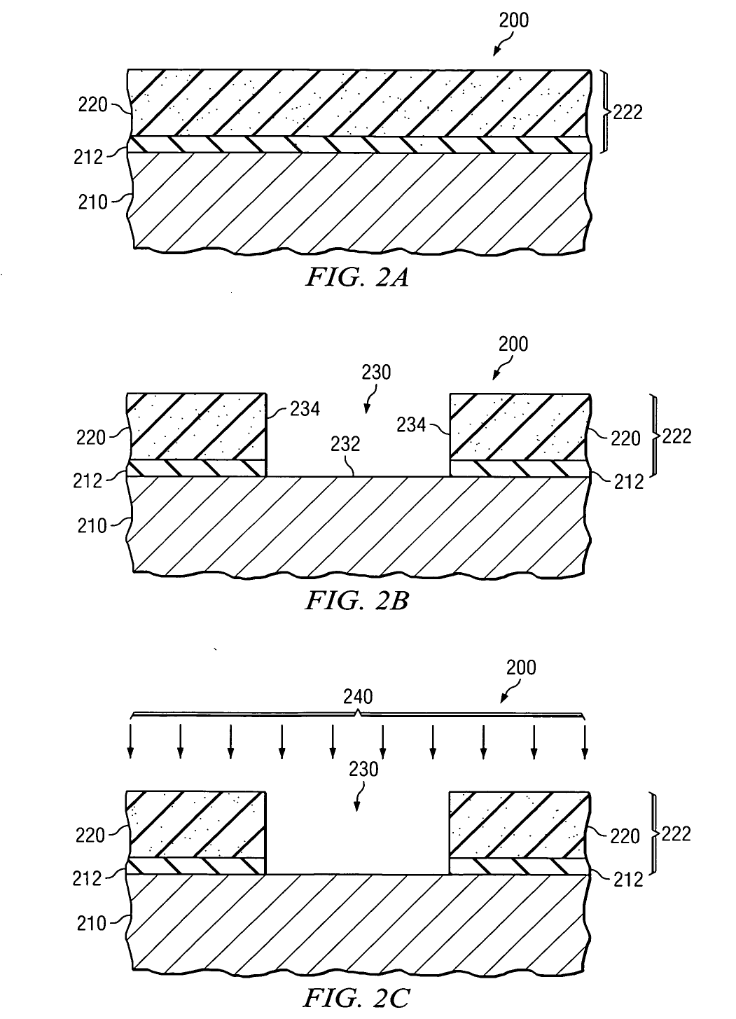

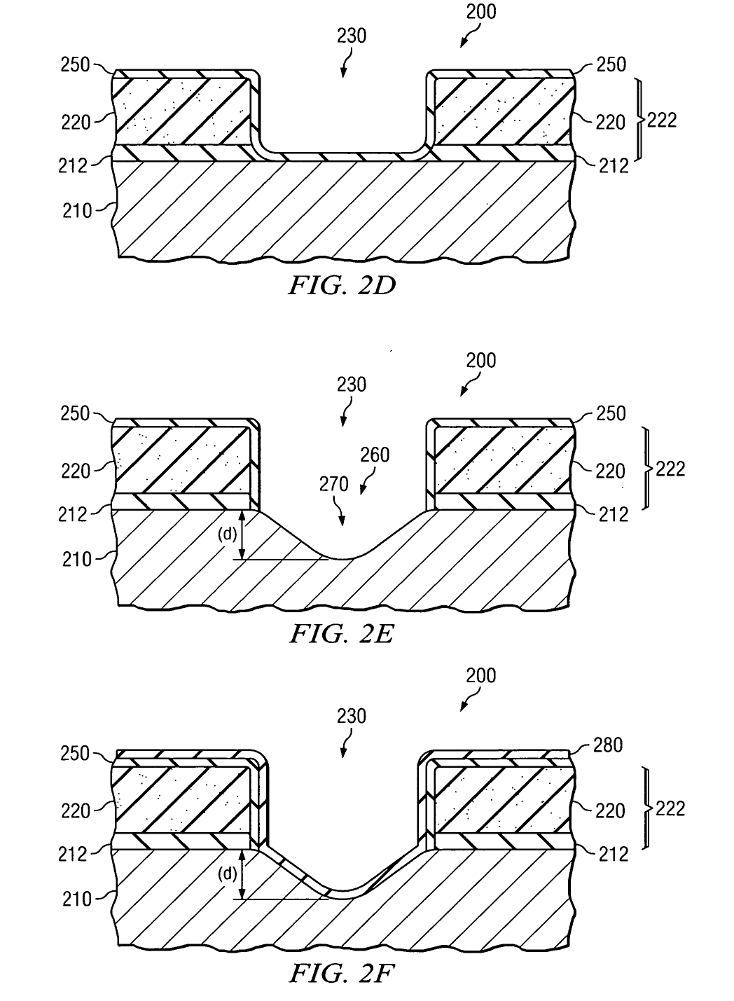

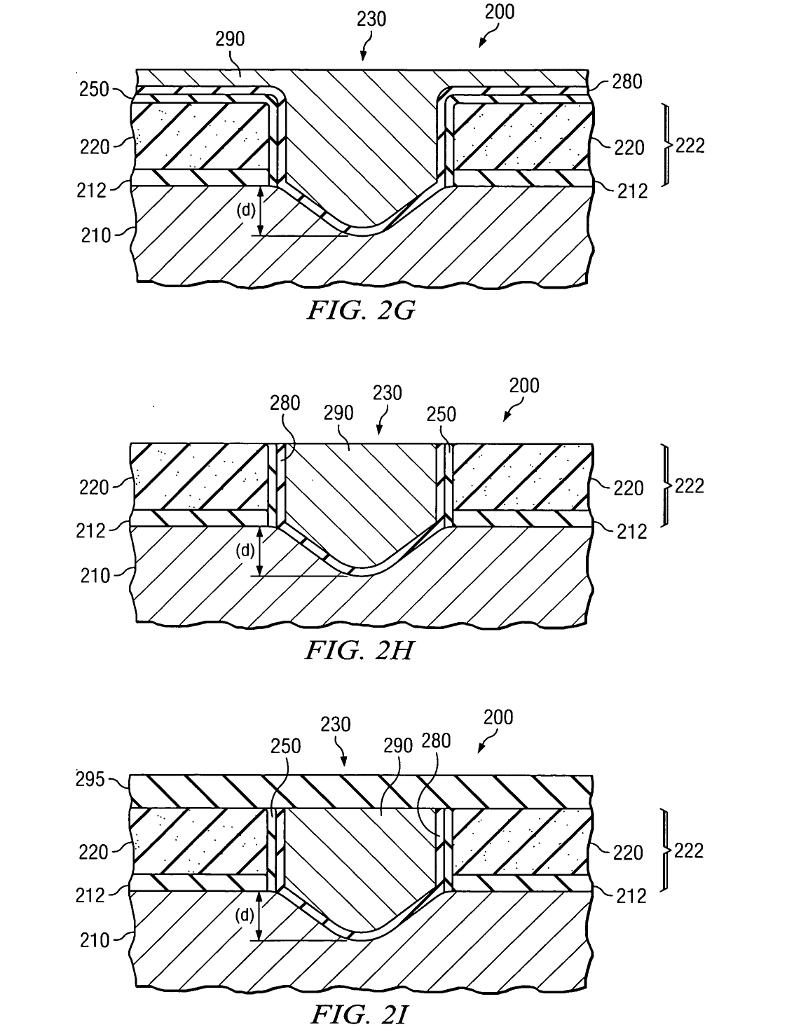

FIGS. 2A-2I, 3A-3L, and 4A-4E are fragmentary cross-sectional diagrams illustrating various embodiments of forming a hole or via in a semiconductor device. Exemplary methods for fabricating exemplary semiconductor devices having improved contact regions and vias will now be described. The methods according to the present embodiments can be implemented in association with the fabrication of integrated circuits and composite transistors illustrated herein, as well as with other transistor structures, not illustrated.

Turning now to FIGS. 2A-2I, a plurality of fragmentary cross-sectional diagrams illustrating a structure 200 in accordance with the present invention are provided. In FIG. 2A, the structure 200 is provided having an electrically conducting material 210, an etch stop layer 212, and a dielectric material 220 formed over etch stop layer 212. Electrically conducting material 210 can comprise copper but can also comprise aluminum, a Cu/Al alloy, Cu/Al/Si alloy, or tungsten. Electrically conducting material 210 can serve as, for example, a metal line or interconnect that is formed over a semiconductor substrate (not shown). The semiconductor substrate is typically comprised of silicon or silicon-germanium, but can also comprise gallium-arsenide or silicon-on-insulator. In certain embodiments, the semiconductor substrate can also include various active and passive devices, which are also not shown in order to simplify the figures. Further, the combination of the semiconductor substrate and the electrically conducting material 210, and other layers formed thereunder, can be considered a substrate.

According to various embodiments, etch stop layer 212 typically comprises SiCN. However, other dielectrics can be used for etch stop layer 212 such as SiN, SiCN, SiCO, SiON, SiOCN, or AlOx. Etch stop layer is used to protect the underlying metal during the via etch process from the dielectric etch chemistry that may result in corrosion of the underlying metal for example. According to various embodiments, there is good etch selectivity between the dielectric and the etch stop layer so that one can use harsher chemistries to etch and clean up the polymer buildup during via etch through the dielectric without harming the metal underneath. Dielectric material 220 can be a low-k dielectric material, such as organosilicate glass (OSG), which is a silicon oxide typically doped with carbon and hydrogen. Exemplary OSG materials include Black Diamond™ from Applied Materials and CORAL™ from Novellus. Other dielectric materials can also be used for dielectric material 220. For example, dielectric material 220 can be SiO₂, either undoped or doped with boron and/or phosphorous, or Si₃N₄. Because etch stop layer 212 and dielectric material 220 are both dielectrics, they can be considered herein to form a dielectric layer 222, as so labeled in FIG. 2A. In certain embodiments, however, etch stop layer 212 may not be used. In such embodiments, dielectric layer 222 would typically comprise dielectric material 220. Moreover, in certain embodiments, an additional dielectric cap (not shown) can be formed over dielectric material 220. This additional dielectric can comprise tetraethyl orthosilicate, Si(OC₂H₅)₄ (TEOS) and can also be considered part of dielectric layer 222.

As shown in FIG. 2B, a hole 230 (also called a via) having a bottom 232 and a sidewall 234 is formed in or through dielectric layer 222. Hole 230 can be formed by conventional VLSI processing steps using photoresist that deposit, pattern, develop, and etch dielectric layer 222, followed by removal of the photoresist by plasma ash process, and finally a wet clean process to remove residual photresist and ash chemistry residue. According to various embodiments, as shown for example in FIG. 2B, hole 230 can expose a portion of electrically conducting material 210 underlying dielectric layer 222.

Structure 200 can be exposed to a degassing process. According to various embodiments, the degassing process can include exposing structure 200 to a temperature of about 200° C. to about 350° C. for about 30 to about 240 seconds. In certain embodiments, the degassing process can include exposing structure 200 to a temperature of about 265° C. for about 150 seconds. The degassing process can be carried out under vacuum or in the presence of a purge gas, such as Ar, at a chamber pressure greater than or equal to 1 torr. Degassing structure 200 can drive out unwanted volatile materials, such as H₂O, hydrodcarbons, or any volatile cleaning solvents from dielectric layer 222. Proper degassing of structure 200 and hole 230 can assist dielectric layer 222 in maintaining a desired dielectric constant throughout processing and in the final device. Sufficient degassing also helps in adhesion of the barrier layer to the dielectric and also improves via resistance distribution by getting rid of unwanted volatile residue from the bottom of the vias.

Structure 200 can also be exposed to a pre-cool process. According to various embodiments, the pre-cool process can include exposing structure 200 to a temperature from about 10° C. to about 50° C. for greater than about 10 seconds after the degas process. In certain embodiments, the pre-cool process can include exposing structure 200 and hole 230 to a temperature of between about 20° C. and about 30° C. using a water-cooled chuck for about 45 seconds. Pre-cooling structure 200 permits subsequent layers deposited in hole 230 and on bottom 232 and sidewall 234 to have a desired grain structure and minimizes agglomeration of metal like Cu on the hole sidewall 234 during the pre-sputter etch clean step which usually follows this pre-cool step.

Various non-volatile residues, such as via etch and ash residues and other impurities can remain on bottom 232 and sidewall 234 after patterning and etching hole 230. Moreover, other impurities, such as copper oxide, can form on the exposed electrically conducting material 210 at bottom 232. These residues and impurities can adversely affect the adhesion strength of barrier layers formed in hole 230 in addition to being a source of yield limiting particle defects. Further, these residues and impurities can also affect the electrical performance of the via giving higher electrical resistance. As such, according to various embodiments, the residues and impurities can be removed in a pre-cleaning process, as shown, for example, in FIG. 2C.

In FIG. 2C, structure 200 and in particular, hole 230 can be exposed to a pre-cleaning step 240. However, it is to be noted that pre-cleaning 240 as described herein does not use a physical etch or impact process to clean bottom 232 or sidewall 234. Rather, pre-cleaning step 240 comprises a chemically reactive and/or a plasma chemical etch process such that the material of pre-cleaning step 240 can chemically interact with and remove the unwanted residues and impurities with a minimal physical etch component. This is in contrast to physical etching process, such as those using heavy atoms, such as argon plasma. Physical etching relies on physically bombarding and etching bottom 232 and sidewall 234. While physical etching may remove unwanted residues and impurities, it can also modify the feature by, for example chamfering the top of the vias. Even worse, however, physical etching can etch the exposed electrically conducting material 210 at bottom 232 and deposit this sputter etched material directly onto dielectric layer 222 and sidewalls 234. The sputtered material can be nanometers in thickness, such as about 1 nm to about 10 nm. As the electrically conducting material 210 typically comprises copper, the copper sputtered onto sidewall 234 can damage the dielectric 222, especially when the dielectric comprises OSG, which can be porous. This can lead to poor performance in the desired semiconductor device and even device reliability failure. For example, copper sputtered onto OSG can diffuse into the OSG and thereby unacceptably increase the dielectric constant of the material and cause reliability failures. Increases in the dielectric constant of dielectric layer 222 can be measured, for example, by monitoring the run current of the relevant device. Devices having degraded dielectric materials typically have a higher run current than those devices with undamaged dielectric materials. Moreover, an energy dispersive x-ray (EDX) technique can be used to detect the presence of copper on sidewalls 234, where the copper is deposited, for example, by a conventional physical etch cleaning.

According to various embodiments, pre-clean 240 can comprise exposing structure 210, and hole 230 in particular, to a reactive ion etch where the material of the chemical etch comprises relatively small atoms, such as hydrogen or helium, separately or in combination. Pre-clean 240 can also include other materials that do not physically etch the interior of hole 230. While not intending to be limited to any one theory, it is believed that pre-clean 240, as described herein, permits a chemical reaction with the residues and/or impurities, that allows the residues and/or impurities to be removed from inside of hole 230.

According to various embodiments, pre-clean 240 can also condition sidewall 234 of dielectric layer 222. For example, pre-clean 240 can reduce the oxygen concentration in thin layer of dielectric layer 222, such as for example, about the first 1 nm to about the first 10 nm, and more particularly, about the first 3 nm to about the first 6 nm. Reducing the oxygen concentration on the surface of the dielectric layer provides improved adhesion between the dielectric and the barrier. Typical reactive pre-clean conditions can use about 5% H₂ balance He gas mixture at a flow rate of about 50 to 150 sccm and a wafer bias of 10 W to 500 W. In certain embodiments, the reactive pre-clean process includes exposing structure 200 to 100 sccm of H₂/He plasma sustained at a RF power of 450 W with a wafer bias of 200 W.

As shown in FIG. 2D, a barrier layer 250 can be deposited on bottom 232 and sidewall 234. Barrier layer 250 may not be deposited conformally using a conventional physical vapor deposition (PVD) technique. Further, barrier layer is also deposited over portions of dielectric layer 222. Barrier layer 250 can be deposited by conventional physical vapor deposition (PVD), chemical vapor deposition (CVD), or atomic layer deposition (ALD) techniques. Barrier layer 250 can also be formed from materials comprising Ta, TaN, TaN(C), TaNSi(C), SiₓN_{y}, TiSiₓN, W, WNₓ, Ru, RuO, Ir, IrO, SiOₓN_{y}, SiC, AlN, or Al₂O₃. Barrier layer 250 is deposited on the substrate and hole 230, including bottom 232 and sidewall 234, and can contact the exposed electrically conducing material 210. The conformality of this barrier layer may or may not be 100% depending upon the deposition technique and process conditions used. According to various embodiments, barrier layer 250 can have a thickness of greater than about 80 Å, and in certain embodiments, can have a thickness of about 275 Å. Typical PVD process conditions to deposit Ta barrier layer 250 include a DC target power of about 15 kW to 25 kW, RF and DC to the re-sputter coil of 0 watts, AC bias to the wafer of about 200 to 500 watts, and Ar gas flow rate of 10 to 30 sccm. An exemplary embodiment for Ta deposition 250 uses 20 kW DC to the target, 230 watts AC bias to the wafer, 0 RF and DC power to the re-sputter coil, and 20 sccm of Ar.

According to various embodiments, structure 200 can be pre-cooled prior to depositing barrier layer 250. One benefit of this pre-cool step prior to barrier film formation step is to keep the underlying metal from agglomerating on the via sidewalls when it gets re-sputtered on the sidewalls during the barrier formation sequence of steps. In contrast, traditional PVD deposition of the barrier yields a relatively thick barrier at the via bottom and a relatively thin barrier on the via sidewalls. A thick barrier at the via bottom results in undesirably high via resistance and too thin of a barrier on the sidewalls is ineffective as a metal barrier. According to various embodiments disclosed herein, a thin barrier film present at the via bottom as opposed to no barrier at all can be achieved. Among other things, this allows for satisfactory electrical contact even in cases where the via is misaligned with respect to the underlying metal line.

To remove barrier from the via bottom and thicken up the barrier on the sidewalls of the via we propose re-sputtering, according to various embodiments, the barrier film can be re-sputtered from the wafer after the initial barrier deposition step as described above. The barrier re-sputter rate can be higher at the bottom of the features, such as a via bottom, as compared to the field. Further, the re-sputtering of the barrier can etch the barrier from the via bottom and re-deposits it on the sidewalls. According to various embodiments, this re-sputter step can remove the barrier from the via bottom. In certain embodiments, this re-sputter step can be carried out without any deposition from the Ta target. According to various embodiments, the DC target power can be 0 watts, the RF power to the re-sputter coil can be about 800 watts, and the wafer bias of about 375 watts in the presence of about 35 sccm of an inert gas, such Ar, flowing in the chamber.

According to various embodiments, as the re-sputter process proceeds, the bottom of the via can be etched deeper into the underlying metal. According to various embodiments, the etch can form a conical hole. As the re-sputter process proceeds, the bottom of the via continues to get etched deeper into the underlying metal forming a conical hole. FIG. 2E shows an etched cone 270 that can be formed in electrically conducting material 210 with the described re-sputter process. According to various embodiments, cone 270 can extend into electrically conducting material 210 to a depth (d) of at least about 300 Å. In certain embodiments, cone 270 can extend into electrically conducting material 210 to depth (d) of about 300 Å to about 1600 Å, and in still further embodiments, cone 270 can extend into electrically conducting material 210 to depth (d) of about 600 Å to about 1200 Å. Moreover, cone 270 can extend into electrically conducting material 210 to depth (d) of about one quarter to about one half the thickness of electrically conducting material. In an exemplary embodiment, electrically conductive material 210 can be about 2700 Å thick. In this case, cone 270 can extend into electrically conducting material to depth (d) of about 675 Å to about 1350 Å. As will be understood, electrically conducting material 210 can have other thicknesses. In any event, in an embodiment, cone 270 may extend about one quarter to about one half the thickness of electrically conducting material.

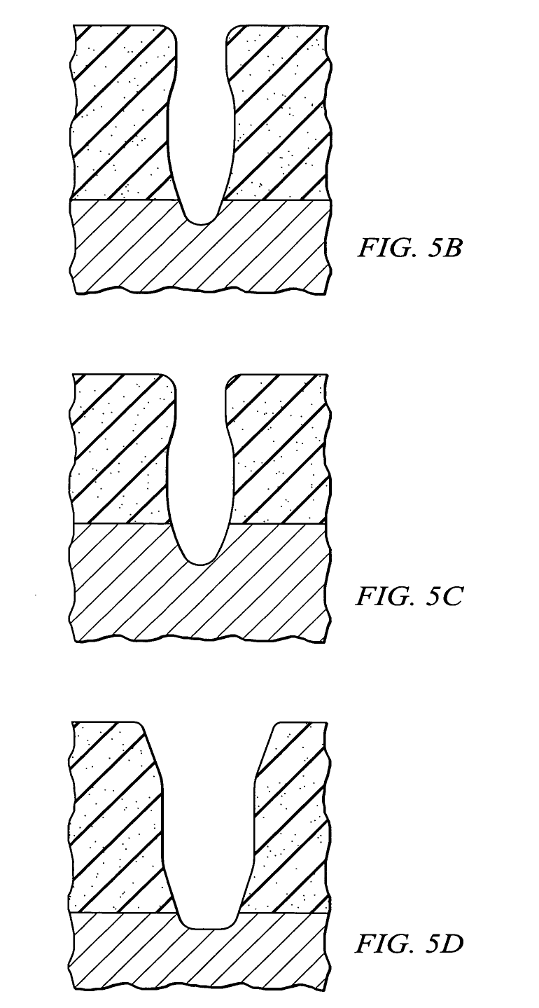

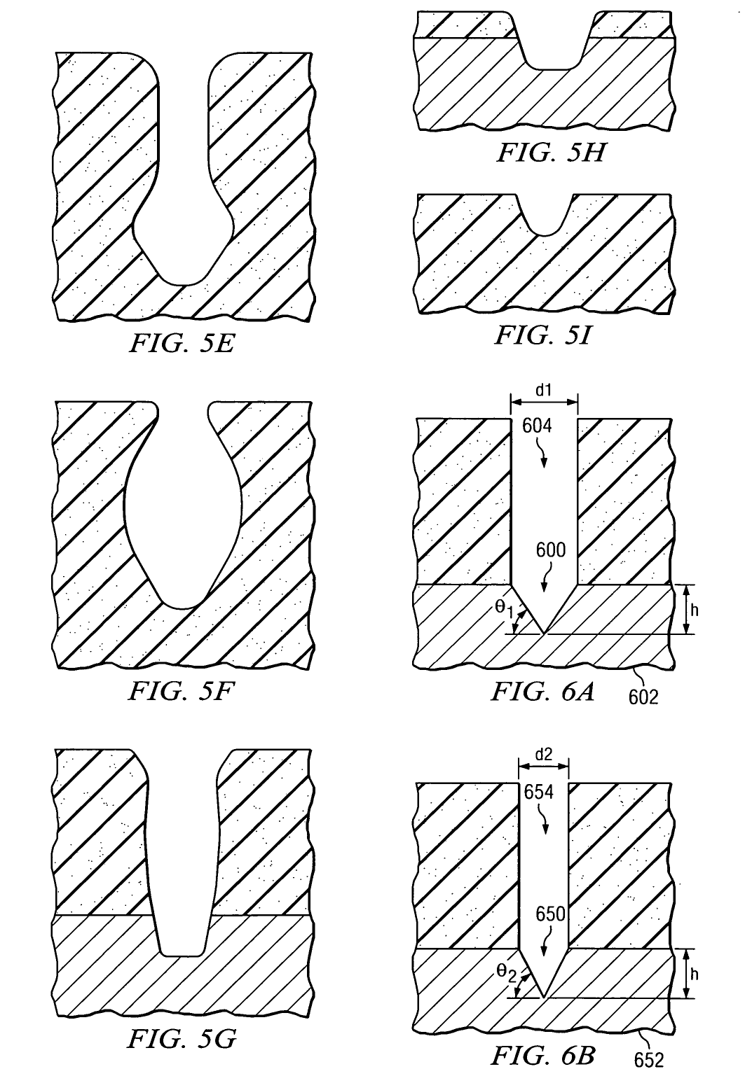

According to various embodiments, cone 270 can comprise a bullet shape extending into electrically conducting material 210. As defined herein, bullet shaped or bullet shape is understood to be generally a shape having a first portion and a second portion adjoining the first portion. The first portion can be generally cylindrical throughout and the second portion can taper to an end. As will be understood, the first portion can include generally straight sidewalls, or sidewalls having a generally concave profile. As will also be understood, the degree of tapering of the second portion can vary according to various embodiments. According to still further embodiments, the second portion can include a first section that tapers and a second section that terminates to a flat end or to a dull point. While not intending to be so limited, exemplary bullet shapes are depicted in FIGS. 5A-5I. According to various embodiments, the bullet shapes depicted in FIGS. 5A-5I can be formed in an insulating material disposed over an electrically conducting material. For example, FIGS. 5A-5D, FIG. 5G, and FIG. 5H show exemplary bullet shapes in an insulating material with the tip of the bullet shapes extending into a conducting material.

According to various embodiments, the cone sidewall angle can vary depending on, for example, the diameter of the hole. Moreover, in some cases, the cone sidewall angle can vary depending on the size of the hole for the same amount that the cone is countersunk into the underlying metal. For example, FIGS. 6A and 6B depict an exemplary graphical description of the cone sidewall angles θ₁ and θ₂ of cone 600 and cone 650, respectively. In the figures, cone 600 has a diameter of d₁ and cone 650 has a diameter of d₂, where d₁>d₂. Moreover, cones 600 and 650 are each countersunk to a similar distance h into the metal layers 602 and 652, respectively at the bottom of holes 604 and 654, respectively. Cone sidewall angle θ₁ is less than cone sidewall angle θ₂. Said another way, a larger diameter hole can have a shallower cone sidewall angle. Thus, the cone sidewall angle can be increased as the hole diameter shrinks. According to various embodiments, the cone sidewall angel can range from about 5 degrees to about 75 degrees depending on the diameter of the hole. As such, as devices continue to decrease in size and contact hole diameter decreases, various embodiments can accommodate the changing requirements. The depth of the cone can be as described herein.

According to other embodiments, cone 270 can have the shape of the second portion of a bullet, as described above, without including the first portion, also described above. Moreover, hole 230 and cone 270 together can form the bullet shape. In such embodiments, dielectric layer 222 can host the first portion of the bullet shape and electrically conducting material 210 can host the second portion of the bullet shape.

According to various embodiments, cone 270 can be formed by using an etch or re-sputter process. This etch or re-sputter process as mentioned above can have a DC target power in the range of 0 to 1200 watts, RF to the re-sputter coil in the range of 400 watts to 1600 watts, and an AC bias to the wafer in the range of 100 watts to 700 watts. The gas flow rate, where the gas can be, for example, Ar, during the re-sputter process can be set in the range between 15 sccm and 50 sccm.

According to various embodiments, extending cone 270 into electrically conducting material 210 as described above, can provide lower via resistance due to direct metal to metal contact with minimal barrier thickness in between and further, it can also improve via reliability because of larger metal to metal contact area as compared to a flat bottom via, which is very susceptible to failures due to voids at the via bottoms that may form due to thermal or electrical stresses or due to electromigration effects. A conical via bottom, counter-sunk deep into the metal underneath can also have improved mechanical stability and resistance to thermal an/or electrical stresses as compared to a flat bottom via that just barely sits on top of the underlying metal. This can be shown by longer electromigration (EM) lifetime tests, which showed that conical bottom vias had an EM lifetime of about 12 to 16 years as compared to 8 to 10 years for a flat bottom vias.

According to various embodiments, forming cone 270 can deposit a layer of electrically conducting material 210, such as copper, and/or barrier layer 250, such as tantalum, onto a portion of barrier layer 250 on sidewall 234. For example, a sputter etch used to form cone 270 sputters barrier layer 250 and a thin amount of copper from bottom 232 of hole 230 directly onto barrier layer 250 formed on sidewall 234. In such embodiments, the sputtered material can form small grains or lamellar structures on barrier layer 250 on sidewall 234. However, because dielectric layer 222 can be covered by barrier layer, 250 the sputtered metal, for e.g., Cu, may not directly contact dielectric layer 222. As such, unwanted materials, such as copper, cannot diffuse into dielectric layer 222, which could degrade the dielectric properties of layer 222 and cause reliability fails. Moreover, in certain embodiments, structure 200 can be pre-cooled, as described above. Cooling structure 200 helps in controlling the lamellae thickness or grain size of the sputtered material. Such control can improve the conductive property of the sputtered material that in turn helps in the via fill process, such as in a Cu electrochemical deposition fill of the via.

According to various embodiments, as shown for example in FIG. 2F, an additional barrier layer 280 can be deposited in hole 230 after the re-sputter step. Additional barrier layer 280 can, but need not, comprise material similar to that used to form barrier layer 250. According to various embodiments, additional barrier layer 280 can be deposited to form a thin layer, for example mostly at the bottom 232 of hole 230, so as to line barrier layer 250 and cone 270. Additional barrier layer 280 can also cover material sputtered onto barrier layer 250.

According to various embodiments, additional barrier layer 280 can be about 25 Å to about 100 Å thick, and in certain embodiments, additional barrier layer 280 can be about 70 Å to about 80 Å thick, and in still further embodiments, it can be about 75 Å thick.

According to various embodiments, barrier layer 250 can be deposited, cone 270 can be formed, and additional barrier layer 280 can be deposited in the same chamber without having to break vacuum. In such embodiments, possible contamination is reduced because structure 200 is not exposed to unwanted materials. Moreover, using a single chamber can reduce processing time and cost. The process conditions used to deposit additional barrier layer 280 can be similar to those used to form first barrier layer 250. However, in certain embodiments, the wafer bias can be kept between 0 and 100 watts.

According to various embodiments, a metal seed layer (not shown) can be deposited in hole 230 and can be used to assist in copper growth during, for example, a Cu ECD electrochemical deposition fill of the hole. The metal seed layer can be a thin layer of copper (400 Å to 1600 Å) deposited on additional barrier layer 280.

As shown in FIG. 2G, a metal layer 290 is deposited over barrier layer 250, the additional barrier layer 280, and the metal seed layer. Metal layer 290 is used to fill the entire via structure including the cone 270 and allows electrical contact to be made to electrically conducting material 210.

As shown in FIG. 2H, over-filled part of the metal layer 290, additional barrier layer 280, and barrier layer 250 can be removed from the top of dielectric material 220 using techniques such as chemical mechanical polishing and other techniques known to one of ordinary skill in the art.

As shown in FIG. 21 additional materials, such as an interlevel dielectric 295 and the like, as will be known in the art, can be deposited over the structure 200 after completing the via for multilevel integration scheme.

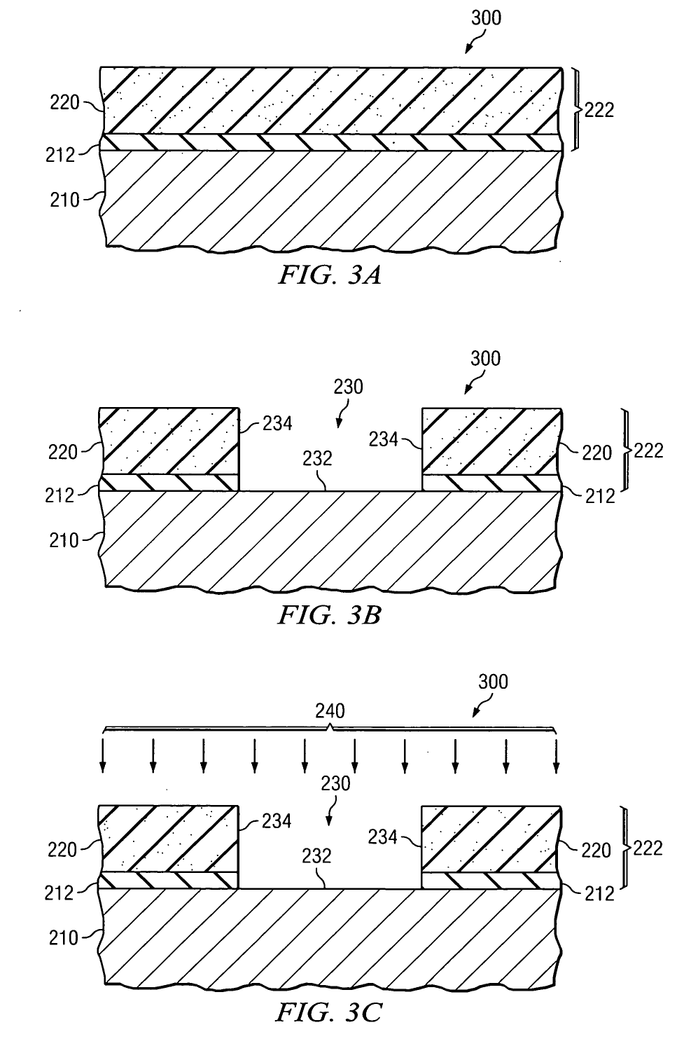

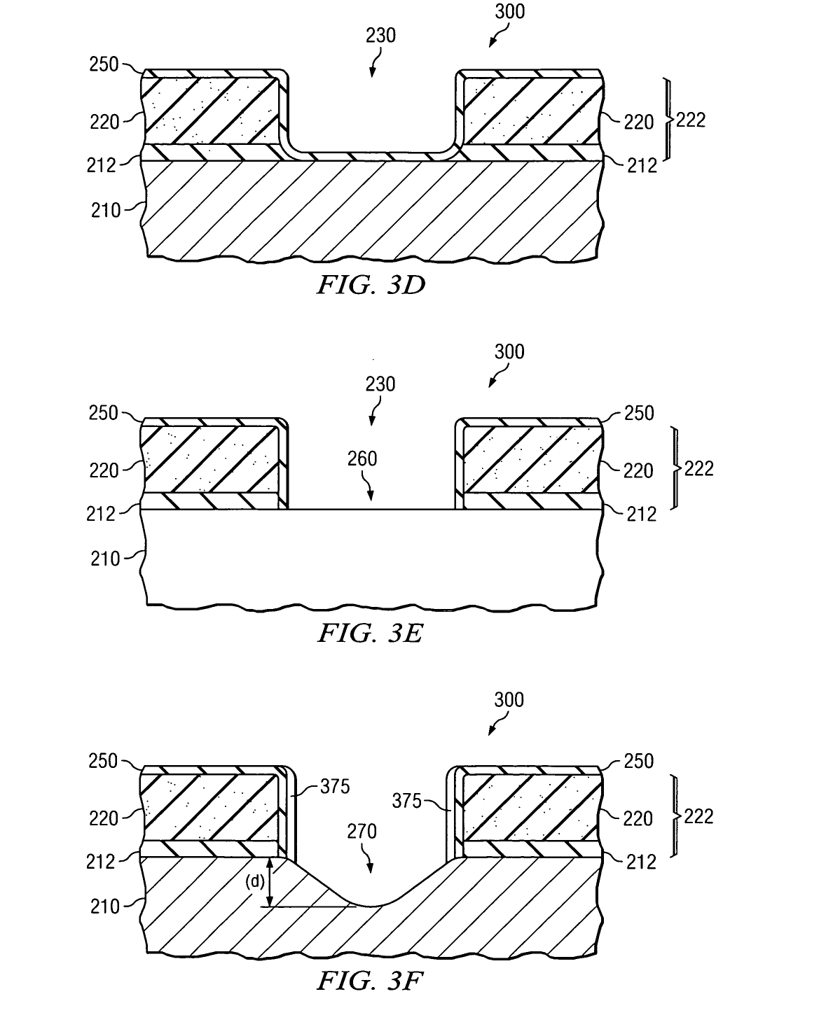

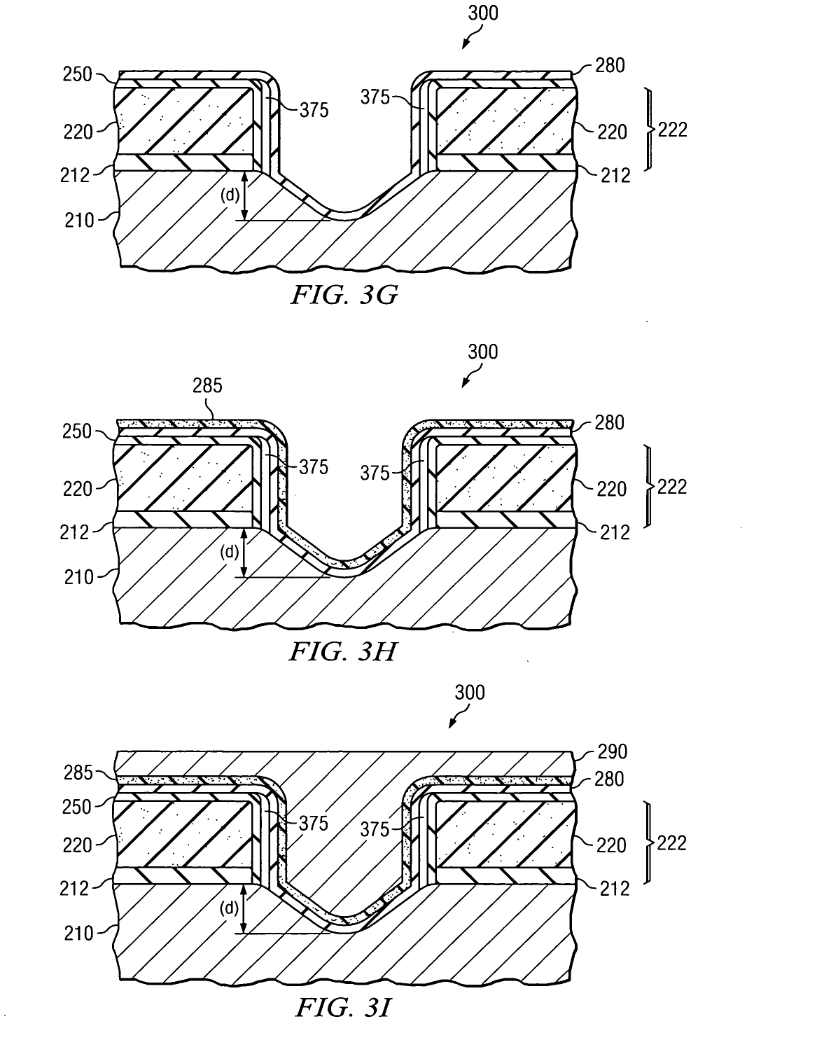

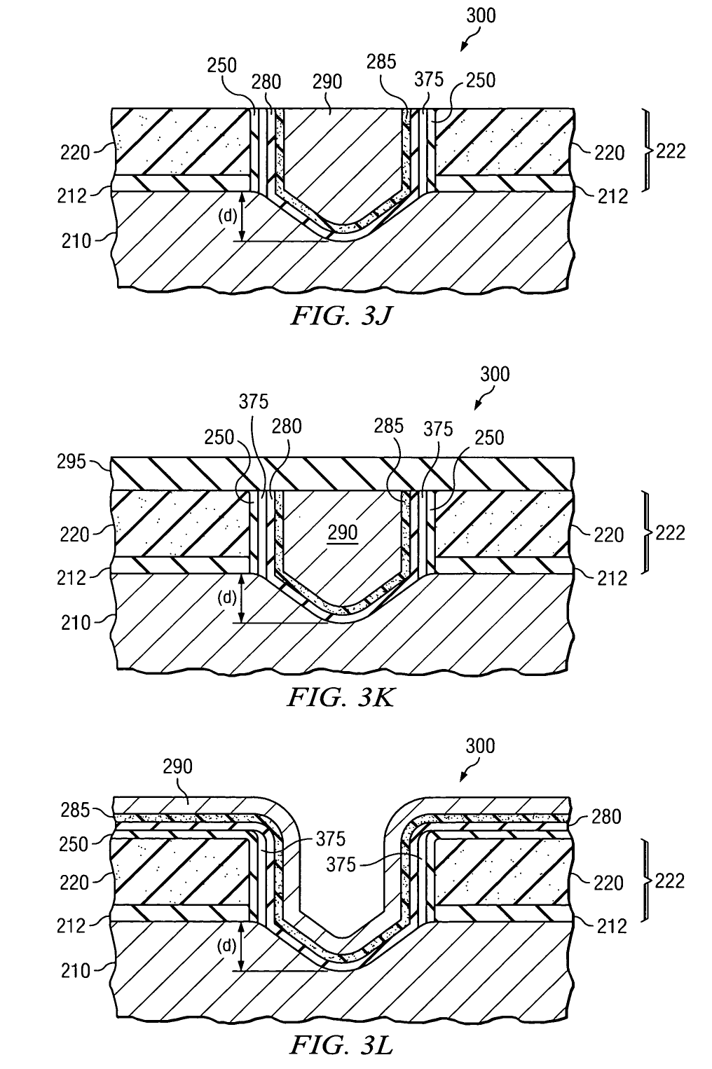

Another embodiment of the invention, shown in FIGS. 3A-3L, can form a semiconductor device 300, such as a contact plug. As shown in FIG. 3A electrically conducting material 210 can be overlaid by etch stop layer 212 and dielectric material 220 that form dielectric layer stack 222. As shown in FIG. 3B, hole 230 having bottom 232 and sidewall 234 can be formed in dielectric layer 222 to expose a portion of underlying electrically conducting material 210. FIG. 3C depicts plasma pre-clean step 240. As mentioned above, plasma pre-cleaning step 240 can comprise a chemical process such that the material of pre-cleaning process chemically interacts with and removes unwanted residues and/or impurities. According to various embodiments, a pre-cool, as described above, can also be applied prior to this pre-clean step. As shown in FIG. 3D, barrier layer 250 is deposited in hole 230 so as to cover exposed electrically conducting material 210 and to line sidewall 234. As shown in FIG. 3E, bottom portion of barrier layer 250 can be re-sputtered so as to expose electrically conducting material 210 at bottom 232 of hole 230 and the re-sputtered material deposits on the sidewall 234.

As shown in FIG. 3F, a cone 270 can be formed by continuing to sputter into electrically conducting material at bottom 232 of hole 230 and this sputtered conducting material deposits onto barrier material 250 on sidewall 234. As shown in FIG. 3F, the sputtered material, as described above, forms a sputtered layer 375 along sidewall 234. According to various embodiments, sputtered layer 375 can be about 1 nm to about 10 nm thick and can be detected by Transmission Electron Microscope (TEM). Further, secondary ion mass spectroscopy (SIMS) or Energy Dispersive X-ray (EDX) can be used to analyze the composition of sputtered layer 375.

As shown in FIG. 3G, additional barrier layer 280 can be deposited in hole 230 so as to cover barrier layer 250, sputtered layer 375, and cone 270. According to various embodiments, barrier layer 250 can be deposited, cone 270 can be formed, and additional barrier layer 280 can be deposited in the same chamber without having to break vacuum. In such embodiments, possible contamination is reduced because structure 300 is not exposed to unwanted materials. Moreover, using a single chamber can reduce processing time and cost.

As shown in FIG. 3H, a metal seed layer 285 can be deposited over barrier layer 250, and additional barrier layer 280 when used. Metal seed layer 285 is also deposited into the cone 270 and allows electrical contact to be made to electrically conducting material 210. According to various embodiments, metal seed layer 285 can be a conductive seed layer, as will be known in the art, that can assist in the formation of an overlying metal. For example, metal seed layer 285 can assist in filling the hole 230 using an electrochemical deposition of Cu or can be used in a CVD process to fill the hole 230 with Cu. According to various embodiments, metal seed layer 285 can be about 1600 Å.

As shown in FIG. 3I, metal layer 290 can be deposited over metal seed layer 285. Metal layer 290 can also be deposited into cone 270 and can allow electrical contact to be made to electrically conducting material 210. According to various embodiments, metal layer 290 can have a thickness of between about 10,000 Å and about 25,000 Å.

As shown in FIG. 3J, over-filled part of metal layer 290, metal seed layer 285, additional barrier layer 280, and barrier layer 250 can be removed from the top of dielectric material 220 using techniques such as chemical mechanical polishing and other techniques known to one of ordinary skill in the art.

As shown in FIG. 3K, additional materials, such as an interlevel dielectric 295 and the like, as will be known in the art, can be deposited over the structure 300 after completing the via for multilevel integration scheme.

As an alternative to over-filling the via with metal layer 290, as shown in FIG. 3I, metal layer 290 can partially fill the via, as shown in FIG. 3L.

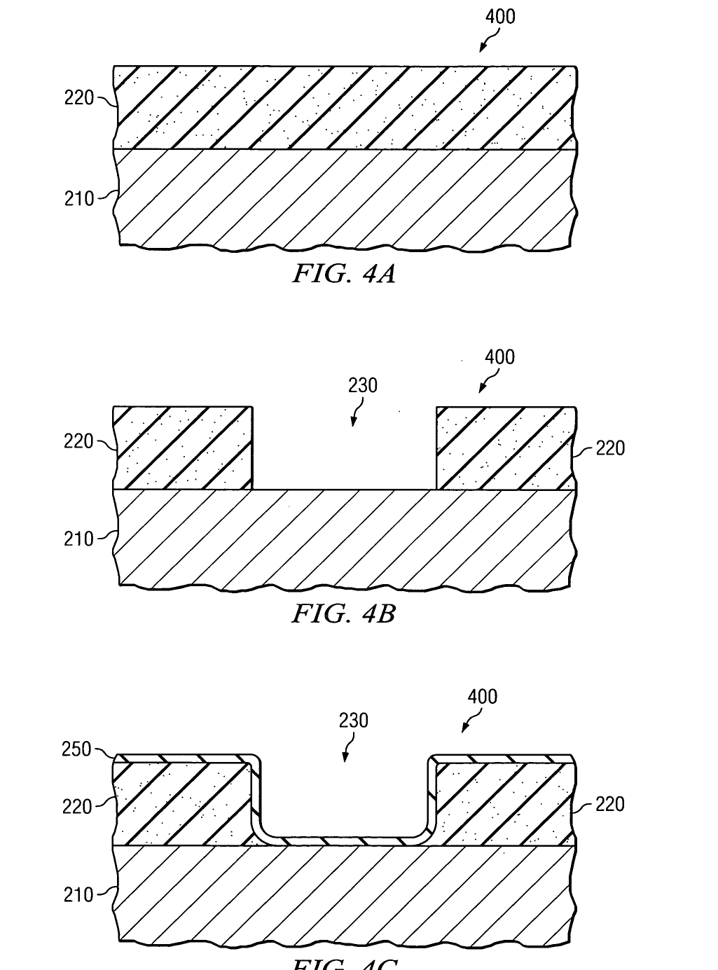

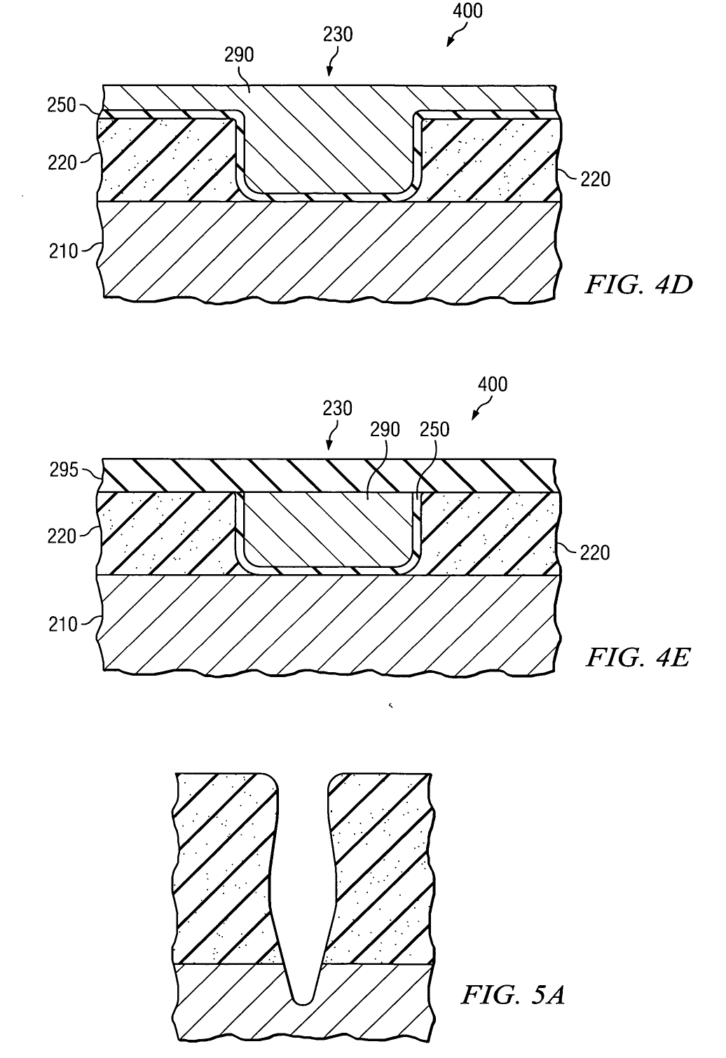

According to other various embodiments, a device and a method for forming the device are shown, for example, in FIGS. 4A-4E. As shown in FIG. 4A, a device 400 includes electrically conducting material 210 overlain by dielectric material 220 or dielectric layer as described above. As shown in FIG. 4B, hole 230 can be formed in dielectric material 220 so as to expose the underlying electrically conducting material 210. According to various embodiments, device 400 can be exposed to a plasma etch process such that the material of the pre-cleaning process chemically interacts with and removes the unwanted residues and impurities. According to various embodiments, a pre-cool, as described above, can also be applied. As shown in FIG. 4C, barrier layer 250 can be deposited in hole 230 so as to cover exposed electrically conducting material 210 and line sidewall 234. According to certain embodiments, additional barrier material (not shown) can be deposited in hole 230 so as to cover barrier layer 250. Further, a metal seed layer can also be formed prior to forming metal layer 290. As shown in FIG. 4D, metal layer 290 is deposited over barrier layer 250 and additional barrier layer 280 when used.

As shown in FIG. 4E, metal layer 290 and barrier layer 250 can be removed from the top of dielectric material 220 using techniques such as chemical mechanical polishing and other techniques known to one of ordinary skill in the art. Further additional materials, such as interlevel dielectric 295, and the like as will be known in the art, can be deposited over the structure 400 after completing the via.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of fabricating an integrated circuit comprising:
patterning a dielectric layer to form a hole having a sidewall and a bottom, wherein the hole exposes an underlying material, the exposed underlying material comprising an electrically conducting material;
exposing the sidewall and the exposed underlying material to a plasma etch;
depositing a barrier layer on the bottom and the sidewall of the hole after the plasma etch;
forming a cone in the underlying material by etching through the barrier layer at the bottom of the hole; depositing a second thin barrier layer inside the hole which includes the cone at the bottom now; and
depositing a metal seedlayer in the hole.

2. The method of fabricating an integrated circuit according to claim 1, wherein the plasma etch comprises a reactive ion etch.

3. The method of fabricating an integrated circuit according to claim 2, wherein the reactive ion etch comprises at least one material selected from hydrogen and helium.

4. The method of fabricating an integrated circuit according to claim 1, further comprising:
exposing the sidewall and the bottom of the hole to a temperature of about 200° C. to about 350° C. prior to depositing the barrier layer.

5. The method of fabricating an integrated circuit according to claim 1, wherein the barrier layer is at least 100 Å thick.

6. The method of fabricating an integrated circuit according to claim 5, wherein the barrier layer comprises tantalum.

7. The method of fabricating an integrated circuit according to claim 1, wherein the step of etching through the barrier layer comprises a sputter etch.

8. The method of fabricating an integrated circuit according to claim 7, wherein the sputter etch comprises argon etch.

9. The method of fabricating an integrated circuit according to claim 1, wherein the cone provides mechanical stability against stress migration related failures in the metal layer in the hole.

10. The method of fabricating an integrated circuit according to claim 1, wherein the cone extends to a depth of at least about 300 Å into the layer of electrically conducting material.

11. The method of fabricating an integrated circuit according to claim 1, wherein the cone extends into the electrically conducting material about one quarter to about one half of the thickness of the electrically conducting material.

12. The method of fabricating an integrated circuit according to claim 1, wherein the cone forms a bullet shape in the layer of electrically conducting material.

13. The method of fabricating an integrated circuit according to claim 1, wherein the sputter etch sputters barrier layer material onto the sidewall of the hole.

14. The method of fabricating an integrated circuit according to claim 1, wherein the cone extends to a depth of about 300 Å to about 1600 Å into the electrically conducting material.

15. The method of fabricating an integrated circuit according to claim 1, wherein there is substantially no electrically conducting material on the sidewall of the hole prior to depositing the barrier layer.

16. The method of fabricating an integrated circuit according to claim 1, wherein the electrically conducting material comprises copper.

17. The method of fabricating an integrated circuit according to claim 16, wherein the dielectric layer comprises a layer of organosilicate glass and a layer of silicon carbonitride (SiCN).

18. The method of fabricating an integrated circuit according to claim 13, further comprising:
depositing about 50 Å to about 100 Å of additional barrier layer in the hole prior to depositing the metal layer.

19. The method of fabricating an integrated circuit according to claim 1, wherein the metal layer comprises copper.

20. The method of fabricating an integrated circuit according to claim 18, wherein the steps of depositing the barrier layer, etching through the barrier layer, and depositing about 50 Å to about 100 Å of additional barrier layer in the hole are conducted in a same chamber.

21. A method of fabricating an integrated circuit comprising:
patterning a dielectric layer to form a hole which exposes an underlying material, the exposed underlying material comprising an electrically conducting material;
exposing a sidewall of the hole and the exposed underlying material to a plasma etch;
depositing a barrier layer onto the sidewall and the exposed underlying material, wherein the sidewall is substantially free of the electrically conducting material; depositing a second thin barrier layer in the hole; and
depositing a metal seed layer in the hole.

22. The method of fabricating an integrated circuit according to claim 21, wherein the plasma etch comprises a reactive ion etch comprising at least one material selected from hydrogen and helium prior to depositing the barrier layer.

23. The method of fabricating an integrated circuit according to claim 21 further comprising:
exposing the sidewall surface and the bottom of the hole to a temperature of about 200° C. to about 350° C. prior to depositing the barrier layer.

24. The method of fabricating an integrated circuit according to claim 21 further comprising:
etching the barrier layer and the electrically conducting material at the bottom of the hole so as to form a cone in the electrically conducting material at the bottom of the hole.

25. The method of fabricating an integrated circuit according to claim 24, wherein the cone extends to a depth of about 300 Å to about 1600 Å into the layer of electrically conducting material.

26. The method of fabricating an integrated circuit according to claim 21 further comprising:
depositing about 50 Å to about 100 Å of additional barrier layer in the hole prior to depositing the metal seed layer.

27. A method of fabricating an integrated circuit comprising:
patterning a dielectric layer to form a hole having a sidewall and a bottom, wherein the hole exposes an underlying material comprising an electrically conducting material;
depositing a barrier layer onto the sidewall and bottom of the hole;
removing the barrier layer at the bottom of the hole to expose the electrically conducting material;
forming a cone in the exposed electrically conducting material, wherein the cone extends to a depth at least 300 Å into the layer of electrically conducting material; and
depositing a metal seed layer over the sidewalls and in the recess.

28. The method of fabricating an integrated circuit according to claim 27 further comprising:
exposing the hole to a reactive ion etch comprising at least one of hydrogen and helium so as to reduce the oxygen concentration in the first 4 nm of the sidewall of the dielectric layer.

29. The method of fabricating an integrated circuit according to claim 27 further comprising:
sputtering a portion of the exposed electrically conducting material onto the sidewall of the hole.

30. The method of fabricating an integrated circuit according to claim 27, wherein the cone forms a bullet shape in the layer of electrically conducting material.

31. The method of fabricating an integrated circuit according to claim 27, wherein the cone extends into the electrically conducting material about one quarter to about one half of the thickness of the electrically conducting material.

32. The method of fabricating an integrated circuit according to claim 27 further comprising:
depositing about 50 Å to about 100 Å of additional barrier layer in the hole prior to depositing the metal seed layer.

33. A method of fabricating an integrated circuit comprising:
patterning a dielectric layer to form a hole having a sidewall and a bottom, wherein the hole exposes an underlying material comprising an electrically conducting material;
exposing the hole to a temperature of about 200° C. to about 350° C.;
cooling the dielectric layer to between about 10° C. to about 50° C.;
depositing a barrier layer onto the sidewall and bottom of the hole;
sputtering through the barrier layer at the bottom of the hole;
sputtering the electrically conducting material to form a cone in the electrically conducting material; and
depositing a metal seed layer into the hole.

34. The method of fabricating an integrated circuit according to claim 33 further comprising:
cleaning the sidewalls and bottom of the hole without sputtering the electrically conducting material.

35. The method of fabricating an integrated circuit according to claim 33, wherein the recess extends to a depth of about 300 Å to about 1600 Å into the electrically conducting material.

36. The method of fabricating an integrated circuit according to claim 33 further comprising:
depositing about 50 Å to about 100 Å of additional barrier layer in the hole prior to depositing the metal seed layer.

37. The method of fabricating an integrated circuit according to claim 36, wherein the steps of depositing the barrier layer, etching through the barrier layer, and depositing about 50 Å to about 100 Å of additional barrier layer in the hole are conducted in a same chamber.

38. An integrated circuit device comprising:
a dielectric layer formed over an underlying material, the underlying material comprising an electrically conducting material;
a hole patterned in the dielectric layer;
a barrier layer lining a portion of the hole;
a cone in the bottom of the hole, wherein the cone extends to a depth at least about 300 Å into the layer of electrically conducting material; and
a metal seed layer lining the hole and the cone.

39. The integrated circuit according to claim 38, wherein there is substantially no electrically conducting material between a sidewall of the hole and the barrier layer.

40. The integrated circuit according to claim 38, wherein the cone forms a bullet shape in the layer of electrically conducting material.

41. The integrated circuit according to claim 38, wherein the electrically conducting material comprises copper.

42. The integrated circuit according to claim 38, wherein the dielectric layer stack comprises a layer of organosilicate glass (OSG), a layer of silicon carbonitride (SiCN) as an etch stop at the bottom, and a layer of tetraorthosilicate (TEOS) at the top of OSG as a dielectric cap layer.

43. An integrated circuit device comprising:
a dielectric layer formed over an underlying material, the underlying material comprising an electrically conducting material;
a hole patterned in the dielectric layer;
a barrier layer lining the hole;
an opening in the barrier layer at a bottom of the hole;
a cone etched in the bottom of the hole exposed by the opening in the barrier layer, wherein the cone extends to about one quarter to about one half of the thickness of the electrically conducting material into the layer of electrically conducting material; and
a metal seed layer lining the hole and the cone.

44. The integrated circuit device according to claim 43, wherein the cone extends to a depth of about 300 Å to about 1600 Å into the electrically conducting material.

45. The integrated circuit device according to claim 43, wherein the electrically conducting material comprises copper.

46. The integrated circuit device according to claim 45, wherein the metal layer comprises copper.

47. The integrated circuit device according to claim 45, wherein barrier layer comprises at least one of tantalum and tantalum nitride.

48. The integrated circuit device according to claim 45 further comprising copper disposed on an outer surface of the barrier layer.

49. An integrated circuit device comprising:
a dielectric layer formed over an underlying material, the underlying material comprising an electrically conducting material;
a hole patterned in the dielectric layer;
a barrier layer lining the hole;
an opening in the barrier layer at a bottom of the hole;
a bullet shaped cone at the bottom of the hole exposed by the opening in the barrier layer and extending into the layer of electrically conducting material; and
a metal seed layer lining the hole and the cone.

50. The integrated circuit device according to claim 49, wherein the recess extends to a depth of about 300 Å to about 1600 Å into the electrically conducting material.

51. The integrated circuit device according to claim 49, wherein the electrically conducting material comprises copper.

52. The integrated circuit device according to claim 49 further comprising:
a film of electrically conducting seed material deposited on an outer surface of the barrier layer.
